(19) United States
(12) Patent Application Publication
(10) Pub. No.: US 2024/0264219 A1
(43) Pub. Date: Aug. 8, 2024

(54) CIRCUIT BOARD FOR SEMICONDUCTOR TESTING AND METHOD OF MANUFACTURING THE SAME

(71) Applicant: MPI CORPORATION, CHU-PEI CITY (TW)

(72) Inventors: SHIH-CHING CHEN, CHU-PEI CITY (TW); JUN-LIANG LAI, CHU-PEI CITY (TW)

(73) Assignee: MPI CORPORATION, CHU-PEI CITY (TW)

(21) Appl. No.: 18/431,470

(22) Filed: Feb. 2, 2024

(30) Foreign Application Priority Data
Feb. 3, 2023 (TW) 112103904

(51) Int. Cl. G01R 31/26; H05K 1/11; H05K 1/18; H05K 3/00

(52) U.S. Cl. CPC G01R 31/2601; H05K 1/112; H05K 1/181; H05K 3/0058; H05K 3/0094

(57) ABSTRACT

A circuit board for a semiconductor testing includes first and second substrates, first and second insulating dielectric layers attached to the lower surface of the first substrate and the upper surface of the second substrate respectively and attached to each other, and electrically conductive fillers disposed in first and second through holes of the first and second insulating dielectric layers and electrically connected with first and second electrically conductive pads of the first and second substrates. For the first through holes, compared with the upper ends thereof, the lower ends thereof have larger width or smaller interval. For the second through holes, compared with the lower ends thereof, the upper ends thereof have larger width or smaller interval. A method of manufacturing the circuit board is also disclosed. Accordingly, an alignment problem in connecting substrates by the insulating dielectric layer may be improved, thereby enhancing the circuit integrity.

### BACKGROUND OF THE INVENTION

### 1. Field of the Invention

The present invention relates generally to circuit boards and more particularly, to a circuit board for semiconductor testing and a method of manufacturing the same.

### 2. Description of the Related Art

In the semiconductor testing field, a probe card is used to serve as the connecting interface between a tester and a device under test (also referred to as DUT hereinafter), such as dies on a wafer. The probe card primarily includes a circuit board and a plurality of probes. A space transformer may be further disposed between the circuit board and the probes. When the device under test is tested by the probe card, the probes are in contact with electrically conductive pads of the device under test, and the circuit board is electrically connected with the tester, so that test signals outputted by the tester are received by the circuit board and then transmitted to the device under test through the probes, or the test result of the device under test is received by the probes and then transmitted to the tester through the circuit board.

In the manufacturing process of the circuit board, there is a certain aspect ratio limitation on the drilling process for the substrate, so it is difficult to reduce the diameter of the holes in the large-thickness substrate, so that the area of the circuit board is difficult to meet the demand for miniaturized size. For solving this problem, a conventional circuit board is structured with a plurality of piled substrates, instead of a single thick substrate. For example, a circuit board 10 shown in FIG. 1 includes a first substrate 11, a second substrate 12, and an insulating dielectric layer 13 disposed between the first and second substrates 11 and 12. Before being piled on one another, the first and second substrates 11 and 12 and the insulating dielectric layer 13 are individually drilled according to demands. Besides, the upper and lower surfaces 112 and 114 of the first substrate 11 and the upper and lower surfaces 122 and 124 of the second substrate 12 are each provided with electrically conductive pads 14 according to demands, and through holes of the insulating dielectric layer 13 are provided therein with electrically conductive adhesive 15. After that, the lower surface 132 of the insulating dielectric layer 13 is attached to the upper surface 122 of the second substrate 12, and then the lower surface 114 of the first substrate 11 is attached to the upper surface 134 of the insulating dielectric layer 13, such that the insulating dielectric layer 13 serves as the adhering material to combine the first and second substrates 11 and 12 with each other, and the circuits of the first substrate 11 are electrically connected with the circuits of the second substrate 12 by the electrically conductive adhesive 15 in the through holes of the insulating dielectric layer 13. Although, in this manner, a large-thickness and small-area circuit board can be manufactured under the aspect ratio limitation on the drilling process, it has a problem that the insulating dielectric layer cannot be flatly attached to the first or second substrate, so as to cause the open circuit problem, which will be specified hereinafter.

Referring to FIG. 1 and FIG. 2, the circuit board 10 can be divided, from the upper surface (i.e. the upper surface 112 of the first substrate 11) or the lower surface (i.e. the lower surface 124 of the second substrate 12) thereof, into a central region 16 (also called BGA region) located at the center of the circuit board 10, and a peripheral region 17 (also called pogo region) located adjacent to the periphery of the circuit board 10. The upper surface 112 of the circuit board 10 is a tester side. The electrically conductive pads 14 of the upper surface 112 of the circuit board 10 located in the peripheral region 17 will be electrically connected to the tester (not shown). The lower surface 124 of the circuit board 10 is a DUT side. The electrically conductive pads 14 of the lower surface 124 of the circuit board 10 located in the central region 16 will be electrically connected with probes (not shown) directly, or electrically connected with probes indirectly through a space transformer (not shown). Based on the above-described electrically connecting relation, for the circuit board 10 of the probe card, the electrically conductive pads 14 in the central region 16 are arranged more densely than the electrically conductive pads 14 in the peripheral region 17, so the intervals between the electrically conductive pads 14 in the central region 16 are smaller than the intervals between the electrically conductive pads 14 in the peripheral region 17.

It can be known from the above description that the lower surface 114 of the first substrate 11 and the upper surface 122 of the second substrate 12 will present the arrangement that the electrically conductive pads 14 in the central region 16 are denser than the electrically conductive pads 14 in the peripheral region 17, which means a situation of uneven pattern of a copper layer. Although the insulating dielectric layer 13 can be made of flexible material to compensate the unevenness of the surface attached thereto, it is difficult to solve the problem that two surfaces attached thereto are both uneven. More specifically speaking, when being attached to the upper surface 122 of the second substrate 12, the lower surface 132 of the insulating dielectric layer 13 can compensate the unevenness of the upper surface 122 of the second substrate 12, so that the electrically conductive adhesive 15 in the through holes of the insulating dielectric layer 13 can be attached to the electrically conductive pads 14 of the upper surface 122 of the second substrate 12. However, when the lower surface 114 of the first substrate 11 is then attached to the upper surface 134 of the insulating dielectric layer 13, the insulating dielectric layer 13 cannot compensate the unevenness of the lower surface 114 of the first substrate 11, so that the electrically conductive adhesive 15 in the through holes of the insulating dielectric layer 13 cannot be attached to the electrically conductive pads 14 of the lower surface 114 of the first substrate 11, resulting in that the circuits of the first substrate 11 are not electrically connected with the circuits of the second substrate 12, thereby causing the open circuit problem.

Besides, no matter the attachment between the first and second substrates 11 and 12 and the insulating dielectric layer 13 has the unevenness problem or not, the through holes of the insulating dielectric layer 13 are very small, and the through holes of the insulating dielectric layer 13 should be aligned with the numerous electrically conductive pads 14 of the lower surface 114 of the first substrate 11 and the upper surface 122 of the second substrate 12. This alignment process may be not accurate enough, which will make the circuits of the first substrate 11 not electrically connected with the circuits of the second substrate 12.

### SUMMARY OF THE INVENTION

The present invention has been accomplished in view of the above-noted circumstances. It is an objective of the present invention to provide a circuit board for semiconductor testing and a method of manufacturing the same, which are improved against the open circuit and alignment problem in connecting a plurality of substrates by the insulating dielectric layer, thereby improving the circuit integrity.

To attain the above objective, the present invention provides a circuit board for semiconductor testing, which includes a first substrate, a second substrate, a first insulating dielectric layer, a second insulating dielectric layer, and at least one electrically conductive filler. The first substrate includes a lower surface, and at least one first electrically conductive pad located on the lower surface of the first substrate. The second substrate includes an upper surface, and at least one second electrically conductive pad located on the upper surface of the second substrate. The first insulating dielectric layer includes an upper surface, a lower surface, and at least one first through hole. The upper surface of the first insulating dielectric layer is attached to the lower surface of the first substrate. The first through hole includes an upper end and a lower end. The upper end of the first through hole is directly connected with the first electrically conductive pad. The upper end and the lower end of the first through hole have a first upper width and a first lower width respectively. The first lower width is larger than the first upper width. The second insulating dielectric layer includes an upper surface, a lower surface, and at least one second through hole. The upper surface and the lower surface of the second insulating dielectric layer are attached to the lower surface of the first insulating dielectric layer and the upper surface of the second substrate respectively. The second through hole includes an upper end and a lower end. The lower end of the second through hole is directly connected with the second electrically conductive pad. The upper end of the second through hole directly communicates with the lower end of the first through hole. The upper end and the lower end of the second through hole have a second upper width and a second lower width respectively. The second upper width is larger than the second lower width. The electrically conductive filler is disposed in the first through hole and the second through hole and electrically connected with the first electrically conductive pad and the second electrically conductive pad.

To attain the above objective, the present invention provides a method of manufacturing a circuit board for semiconductor testing. The method includes the steps of:
providing a first substrate and a second substrate, the first substrate including a lower surface and at least one first electrically conductive pad located on the lower surface of the first substrate, the second substrate including an upper surface and at least one second electrically conductive pad located on the upper surface of the second substrate;
attaching an upper surface of a first insulating dielectric layer to the lower surface of the first substrate and providing the first insulating dielectric layer with at least one first through hole by drilling in a way that an upper end of the first through hole is directly connected with the first electrically conductive pad, a lower end of the first through hole is located on a lower surface of the first insulating dielectric layer, the upper end and the lower end of the first through hole have a first upper width and a first lower width respectively, and the first lower width is larger than the first upper width;
attaching a lower surface of a second insulating dielectric layer to the upper surface of the second substrate and providing the second insulating dielectric layer with at least one second through hole by drilling in a way that a lower end of the second through hole is directly connected with the second electrically conductive pad, an upper end of the second through hole is located on an upper surface of the second insulating dielectric layer, the upper end and the lower end of the second through hole have a second upper width and a second lower width respectively, and the second upper width is larger than the second lower width; and
disposing an electrically conductive filler in the first through hole and the second through hole and attaching the lower surface of the first insulating dielectric layer and the upper surface of the second insulating dielectric layer to each other in a way that the upper end of the second through hole directly communicates with the lower end of the first through hole, and the electrically conductive filler is electrically connected with the first electrically conductive pad and the second electrically conductive pad.

As a result, the aforementioned circuit board can be manufactured by the aforementioned method. In the manufacturing process, the upper surface of the first insulating dielectric layer can compensate the unevenness of the lower surface of the first substrate, and the lower surface of the second insulating dielectric layer can compensate the unevenness of the upper surface of the second substrate. Therefore, the lower surface of the first insulating dielectric layer and the upper surface of the second insulating dielectric layer are attached to each other in a quite flat manner, making the electrically conductive filler electrically connected with the first electrically conductive pad and the second electrically conductive pad positively, thereby preventing the circuit board, after the manufacture thereof is accomplished, from the open circuit problem. Besides, the first lower width of the first through hole is larger than the first upper width, and the second upper width of the second through hole is larger than the second lower width. Such features represent that the first and second through holes are manufactured with relatively wider openings on the lower surface of the first insulating dielectric layer and the upper surface of the second insulating dielectric layer. Therefore, during attaching the lower surface of the first insulating dielectric layer and the upper surface of the second insulating dielectric layer to each other, it is relatively easier to align the first through hole and the second through hole with each other, bringing the alignment process great accuracy, thereby improving the circuit integrity.

The first and second insulating dielectric layers may be made of the same material. Therefore, even though where the first and second insulating dielectric layers are connected to each other is provided with the wide openings of the first and second through holes and thereby causes small attached area between the first and second insulating dielectric layers, the first and second insulating dielectric layers can be still attached to each other firmly. Relatively, the first and second insulating dielectric layers are usually different in material from the first and second substrates, so the respective attachment of the first and second insulating dielectric layers to the first and second substrates needs relatively larger bonding force. However, in the condition that the intervals of the electrically conductive pads of the first and second substrates are very small, such as those in the BGA region, the areas located between the adjacent electrically conductive pads of the first and second substrates for the first and second insulating dielectric layers to be attached thereto are very small. By the above-described feature of the present invention that the first and second through holes have an end connected with the first and second electrically conductive pads and smaller in width than the other end, the first and second insulating dielectric layers can be prevented from too small area thereof being attached to the first and second substrates, so as to ensure enough bonding force between the first and second insulating dielectric layers and the first and second substrates, thereby avoiding the substrate coming off problem.

Preferably, the first substrate includes a plurality of first electrically conductive pads. The first insulating dielectric layer includes a plurality of first through holes. The upper ends of the first through holes are directly connected with the first electrically conductive pads respectively. The smallest distance between the upper ends of two adjacent first through holes is defined as a first upper interval. The first upper interval is larger than the first upper width of the first through hole. The second substrate includes a plurality of second electrically conductive pads. The second insulating dielectric layer includes a plurality of second through holes. The upper ends of the second through holes directly communicate with the lower ends of the first through holes respectively. The lower ends of the second through holes are directly connected with the second electrically conductive pads respectively. The smallest distance between the lower ends of two adjacent second through holes is defined as a second lower interval. The second lower interval is larger than the second lower width of the second through hole.

As a result, where the first and second insulating dielectric layers are attached to the first and second substrates is larger in area than where the first and second through holes are connected with the first and second substrates, which can further ensure enough bonding force between the first and second insulating dielectric layers and the first and second substrates to avoid the substrate coming off problem.

Preferably, the smallest distance between the lower ends of two adjacent first through holes is defined as a first lower interval. The first lower interval is smaller than the first upper interval. The smallest distance between the upper ends of two adjacent second through holes is defined as a second upper interval. The second upper interval is smaller than the second lower interval.

As a result, where the first and second insulating dielectric layers are attached to each other is smaller in area than where the first and second insulating dielectric layers are attached to the first and second substrates respectively. The first and second insulating dielectric layers can be made of the same material to be relatively easier to be attached to each other firmly. Therefore, even though the attached area between the first and second insulating dielectric layers is relatively smaller, the enough bonding force can be still attained. The first and second insulating dielectric layers are usually different in material from the first and second substrates, so the relatively larger bonding force is needed. The relatively larger area of where the first and second insulating dielectric layers are attached to the first and second substrates can ensure enough bonding force between the first and second insulating dielectric layers and the first and second substrates, thereby avoiding the substrate coming off problem.

To attain the aforementioned objective of the present invention, the present invention further provides another circuit board for semiconductor testing, and a method of manufacturing the same.

The circuit board includes a first substrate, a second substrate, a first insulating dielectric layer, a second insulating dielectric layer, and at least one electrically conductive filler. The first substrate includes a lower surface, and a plurality of first electrically conductive pads located on the lower surface of the first substrate. The second substrate includes an upper surface, and a plurality of second electrically conductive pads located on the upper surface of the second substrate. The first insulating dielectric layer includes an upper surface, a lower surface, and a plurality of first through holes. The upper surface of the first insulating dielectric layer is attached to the lower surface of the first substrate. Each of the first through holes includes an upper end and a lower end. The upper ends of the first through holes are directly connected with the first electrically conductive pads respectively. The smallest distance between the upper ends of two adjacent first through holes is defined as a first upper interval. The smallest distance between the lower ends of two adjacent first through holes is defined as a first lower interval. The first lower interval is smaller than the first upper interval. The second insulating dielectric layer includes an upper surface, a lower surface, and a plurality of second through holes. The upper surface and the lower surface of the second insulating dielectric layer are attached to the lower surface of the first insulating dielectric layer and the upper surface of the second substrate respectively. Each of the second through holes includes an upper end and a lower end. The lower ends of the second through holes are directly connected with the second electrically conductive pads respectively. The upper ends of the second through holes directly communicate with the lower ends of the first through holes respectively. The smallest distance between the lower ends of two adjacent second through holes is defined as a second lower interval. The smallest distance between the upper ends of two adjacent second through holes is defined as a second upper interval. The second upper interval is smaller than the second lower interval. Each of the electrically conductive fillers is disposed in the first through hole and the second through hole, which communicate with each other, and electrically connected with the first electrically conductive pad and the second electrically conductive pad.

The method of manufacturing the circuit board includes the steps of:
providing a first substrate and a second substrate, the first substrate including a lower surface and a plurality of first electrically conductive pads located on the lower surface of the first substrate, the second substrate including an upper surface and a plurality of second electrically conductive pads located on the upper surface of the second substrate;
attaching an upper surface of a first insulating dielectric layer to the lower surface of the first substrate and providing the first insulating dielectric layer with a plurality of first through holes by drilling, each of the first through holes including an upper end and a lower end, the upper ends of the first through holes being directly connected with the first electrically conductive pads respectively, the lower ends of the first through holes being located on a lower surface of the first insulating dielectric layer, the smallest distance between the upper ends of two adjacent first through holes being defined as a first upper interval, the smallest distance between the lower ends of two adjacent first through holes being defined as a first lower interval, the first lower interval being smaller than the first upper interval;
attaching a lower surface of a second insulating dielectric layer to the upper surface of the second substrate and providing the second insulating dielectric layer with a plurality of second through holes by drilling, each of the second through holes including an upper end and a lower end, the lower ends of the second through holes being directly connected with the second electrically conductive pads respectively, the upper ends of the second through holes being located on an upper surface of the second insulating dielectric layer, the smallest distance between the lower ends of two adjacent second through holes being defined as a second lower interval, the smallest distance between the upper ends of two adjacent second through holes being defined as a second upper interval, the second upper interval being smaller than the second lower interval; and
disposing a plurality of electrically conductive fillers in the first through holes and the second through holes and attaching the lower surface of the first insulating dielectric layer and the upper surface of the second insulating dielectric layer to each other in a way that the upper ends of the second through holes directly communicate with the lower ends of the first through holes respectively, and each of the electrically conductive fillers is disposed in the first through hole and the second through hole, which communicate with each other, and electrically connected with the first electrically conductive pad and the second electrically conductive pad.

As a result, in the above-described manufacturing process of the circuit board, the upper surface of the first insulating dielectric layer can compensate the unevenness of the lower surface of the first substrate, and the lower surface of the second insulating dielectric layer can compensate the unevenness of the upper surface of the second substrate. Therefore, the lower surface of the first insulating dielectric layer and the upper surface of the second insulating dielectric layer are attached to each other in a quite flat manner, making the electrically conductive fillers electrically connected with the first electrically conductive pads and the second electrically conductive pads positively, thereby preventing the circuit board, after the manufacture thereof is accomplished, from the open circuit problem. Besides, the first lower interval is smaller than the first upper interval, and the second upper interval is smaller than the second lower interval. Such features represent that compared with the area of where the first and second insulating dielectric layers are attached to the first and second substrates respectively, the area of where the first and second insulating dielectric layers are connected with each other is smaller, so that the first and second insulating dielectric layers have surfaces connected with each other and provided thereon with relatively wider openings of the first and second through holes. Therefore, during attaching the lower surface of the first insulating dielectric layer and the upper surface of the second insulating dielectric layer to each other, it is relatively easier to align the first through holes and the second through holes with each other, bringing the alignment process great accuracy, thereby improving the circuit integrity. Besides, the first and second insulating dielectric layers can be made of the same material, so that even though the attached area thereof is relatively smaller, they can be still attached to each other firmly. The first and second insulating dielectric layers are connected with the first and second substrates in a different material manner, and the attached area thereof is relatively larger to attain great bonding force, so the substrate coming off problem is avoided.

Preferably, the upper end and the lower end of the first through hole have a first upper width and a first lower width respectively. The first upper interval is larger than the first upper width of the first through hole. The upper end and the lower end of the second through hole have a second upper width and a second lower width respectively. The second lower interval is larger than the second lower width of the second through hole. As a result, where the first and second insulating dielectric layers are attached to the first and second substrates is larger in area than where the first and second through holes are connected with the first and second substrates, which can further ensure enough bonding force between the first and second insulating dielectric layers and the first and second substrates, thereby avoiding the substrate coming off problem.

Preferably, the upper end and the lower end of the first through hole have a first upper width and a first lower width respectively. The first lower width is larger than the first upper width. The upper end and the lower end of the second through hole have a second upper width and a second lower width respectively. The second upper width is larger than the second lower width.

As a result, the first and second insulating dielectric layers have surfaces connected with each other and provided thereon with relatively wider openings of the first and second through holes, which makes it relatively easier to align the first through holes and the second through holes with each other, bringing the alignment process great accuracy, thereby improving the circuit integrity. Besides, the first and second through holes have an end connected with the first and second electrically conductive pads and relatively smaller in width, which can prevent the first and second insulating dielectric layers from too small area thereof being attached to the first and second substrates, so as to ensure enough bonding force between the first and second insulating dielectric layers and the first and second substrates, thereby avoiding the substrate coming off problem.

Preferably, the first electrically conductive pad of the first substrate has a bottom surface directly connected with the upper end of the first through hole, and an outer peripheral surface located on the outer periphery of the bottom surface. The first insulating dielectric layer is attached to the outer peripheral surface and a part of the bottom surface of the first electrically conductive pad. The second electrically conductive pad of the second substrate has a top surface directly connected with the lower end of the second through hole, and an outer peripheral surface located on the outer periphery of the top surface. The second insulating dielectric layer is attached to the outer peripheral surface and a part of the top surface of the second electrically conductive pad.

As a result, the attached area between the first insulating dielectric layer and the first substrate includes the attached area provided by the interval between the adjacent first electrically conductive pads, and the attached area between the first insulating dielectric layer and the outer peripheral surfaces and the partial bottom surfaces of the first electrically conductive pads. The attached area between the second insulating dielectric layer and the second substrate includes the attached area provided by the interval between the adjacent second electrically conductive pads, and the attached area between the second insulating dielectric layer and the outer peripheral surfaces and the partial top surfaces of the second electrically conductive pads. That makes the attached area between the first and second insulating dielectric layers and the first and second substrates relatively larger. In particular, in the condition that the intervals between the electrically conductive pads of the first and second substrates are very small, such as those in the BGA region, this feature is effective in increasing the attached area between the first and second insulating dielectric layers and the first and second substrates, thereby increasing the bonding force between the first and second insulating dielectric layers and the first and second substrates.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is an exploded schematic sectional view of a conventional circuit board for semiconductor testing;

FIG. 2 is a schematic top view of the conventional circuit board for semiconductor testing;

FIG. 3 is a schematic sectional view of a circuit board for semiconductor testing according to a preferred embodiment of the present invention;

FIG. 4 to FIG. 7 are schematic sectional views showing a method of manufacturing the circuit board for semiconductor testing according to the preferred embodiment of the present invention;

FIG. 8 is a schematic perspective view of an electrically conductive filler of the circuit board for semiconductor testing according to the preferred embodiment of the present invention;

FIG. 9 is similar to FIG. 8, but showing the configuration that the electrically conductive filler has an offset; and

FIG. 10 and FIG. 11 are similar to FIG. 3, but showing the configuration that the electrically conductive filler has the offset.

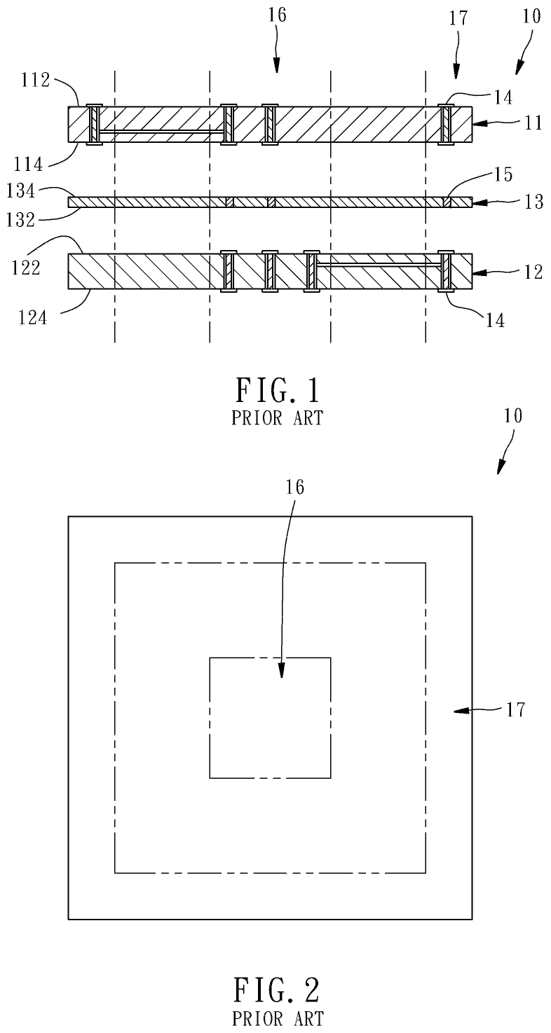

### DETAILED DESCRIPTION OF THE INVENTION

First of all, it is to be mentioned that same or similar reference numerals used in the following embodiments and the appendix drawings designate same or similar elements or the structural features thereof throughout the specification for the purpose of concise illustration of the present invention. It should be noticed that for the convenience of illustration, the components and the structure shown in the figures are not drawn according to the real scale and amount, and the features mentioned in each embodiment can be applied in the other embodiments if the application is possible in practice. Besides, when it is mentioned that an element is disposed on another element, it means that the former element is directly disposed on the latter element, or the former element is indirectly disposed on the latter element through one or more other elements between aforesaid former and latter elements. When it is mentioned that an element is directly disposed on another element, it means that no other element is disposed between aforesaid former and latter elements.

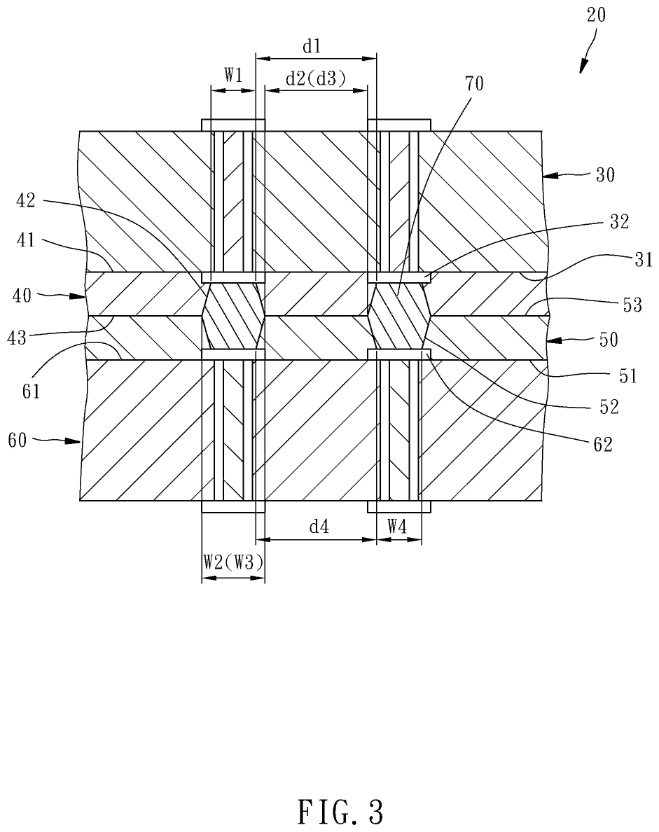

Referring to FIG. 3, a circuit board 20 for semiconductor testing according to a preferred embodiment of the present invention includes a first substrate 30, a first insulating dielectric layer 40, a second insulating dielectric layer 50 and a second substrate 60, which are piled from the top to the bottom, and at least one electrically conductive filler 70.

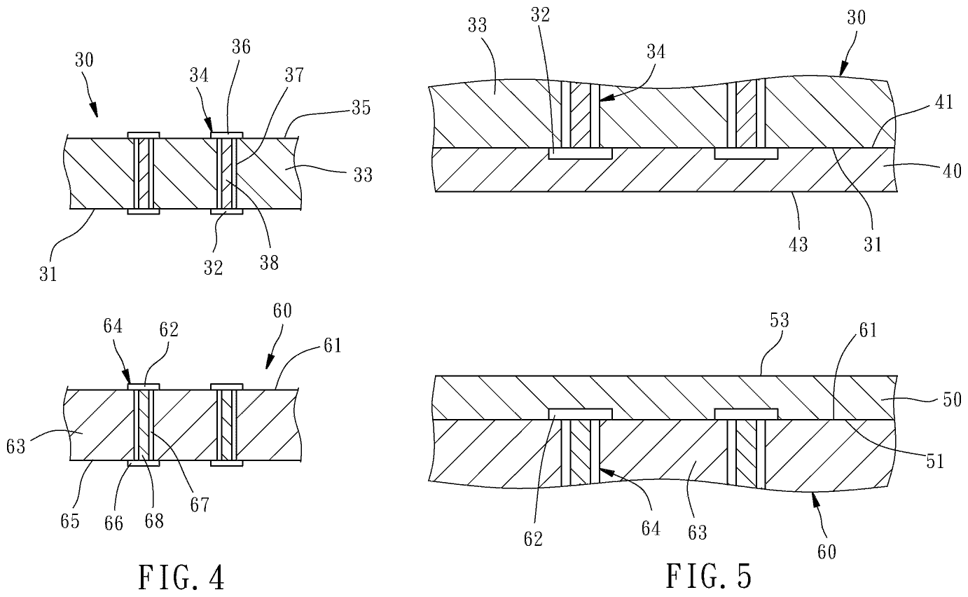

A method of manufacturing the circuit board 20 will be described hereinafter, and the detailed structure of each component of the circuit board 20 will be specified at the same time. The method of manufacturing the circuit board 20 includes the following steps.
a) As shown in FIG. 4, provide the first substrate 30 and the second substrate 60. The first substrate 30 includes a lower surface 31, and at least one first electrically conductive pad 32 located on the lower surface 31. The second substrate 60 includes an upper surface 61, and at least one second electrically conductive pad 62 located on the upper surface 61.

It should be mentioned here that in the figures of the present invention, the first substrate 30 includes a plate 33 and a plurality of vertical conductive vias 34, and the second substrate 60 includes a plate 63 and a plurality of vertical conductive vias 64. In practice, each of the first substrate 30 and the second substrate 60 is a multi-layer circuit board including multiple base material layers press laminated together. The base material layers are made of dielectric material. A part of the connected surfaces of the base material layers are provided with horizontal conductive lines (not shown). After the manufacture of the base material layers and the horizontal conductive lines is accomplished, the vertical conductive vias 34 or 64 are provided. In other words, each plate 33 or 63 is actually composed of multiple base material layers, and each plate 33 or 63 is provided therein with horizontal conductive lines. However, this part is less related to the technical features of the present invention. For the simplification of the figures and the convenience of illustration, in the figures of the present invention, each plate 33 or 63 is shown as integrity and the horizontal conductive lines are not shown.

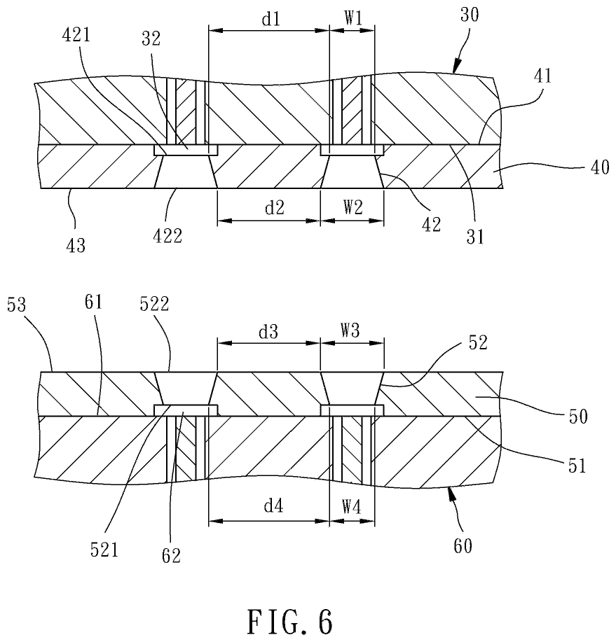

The aforementioned vertical conductive vias 34 and 64 are usually electroplated vias, which are provided in a way that the plates 33 and 63 are firstly provided therethrough with through holes by mechanical drilling or laser drilling, and then the inner walls of the through holes and the openings at two ends of the through holes are electroplated with copper. As a result, the vertical conductive via 34 of the first substrate 30 not only includes an aforementioned first electrically conductive pad 32 located on the lower surface 31, but also includes a first electrically conductive pad 36 located on the upper surface 35, and a conductive inner wall 37 electrically connecting the first electrically conductive pad 32 with the first electrically conductive pad 36. Likewise, the vertical conductive via 64 of the second substrate 60 not only includes an aforementioned second electrically conductive pad 62 located on the upper surface 61, but also includes a second electrically conductive pad 66 located on the lower surface 65, and a conductive inner wall 67 electrically connecting the second electrically conductive pad 62 with the second electrically conductive pad 66. Besides, each vertical conductive via 34 or 64 can be further stuffed therein with an insulator 38 or 68.
b) As shown in FIG. 5, attach an upper surface 41 of the first insulating dielectric layer 40 to the lower surface 31 of the first substrate 30 and provide the first insulating dielectric layer 40 with at least one first through hole 42 (as shown in FIG. 6) by drilling in a way that an upper end 421 of the first through hole 42 is directly connected with the first electrically conductive pad 32, a lower end 422 of the first through hole 42 is located on a lower surface 43 of the first insulating dielectric layer 40, the upper end 421 and the lower end 422 of the first through hole 42 have a first upper width W1 and a first lower width W2 respectively, and the first lower width W2 is larger than the first upper width W1.
c) As shown in FIG. 5, attach a lower surface 51 of the second insulating dielectric layer 50 to the upper surface 61 of the second substrate 60 and provide the second insulating dielectric layer 50 with at least one second through hole 52 (as shown in FIG. 6) in a way that a lower end 521 of the second through hole 52 is directly connected with the second electrically conductive pad 62, an upper end 522 of the second through hole 52 is located on an upper surface 53 of the second insulating dielectric layer 50, the upper end 522 and the lower end 521 of the second through hole 52 have a second upper width W3 and a second lower width W4 respectively, and the second upper width W3 is larger than the second lower width W4.

Specifically speaking, the first insulating dielectric layer 40 and the second insulating dielectric layer 50 usually have certain flexibility and viscosity. For example, the first and second insulating dielectric layers 40 and 50 may be films made of glass fiber and impregnated with resin to become films with adhesive property. In FIG. 5, the upper surface 41 of the first insulating dielectric layer 40 is directly attached to the lower surface 31 of the first substrate 30, and meanwhile covers the first electrically conductive pads 32. Although the first electrically conductive pads 32 protrude from the lower surface 31 of the first substrate 30 and thereby cause the first substrate 30 an uneven surface for the connection with the first insulating dielectric layer 40, the first insulating dielectric layer 40, by the flexibility thereof, can compensate the unevenness. Likewise, the lower surface 51 of the second insulating dielectric layer 50 is directly attached to the upper surface 61 of the second substrate 60, and meanwhile covers the second electrically conductive pads 62. Although the second electrically conductive pads 62 protrude from the upper surface 61 of the second substrate 60 and thereby cause the second substrate 60 an uneven surface for the connection with the second insulating dielectric layer 50, the second insulating dielectric layer 50, by the flexibility thereof, can compensate the unevenness. Therefore, after the first and second insulating dielectric layers 40 and 50 are attached to the first and second substrates 30 and 60 respectively, the lower surface 43 of the first insulating dielectric layer 40 and the upper surface 53 of the second insulating dielectric layer 50 can be still maintained flat, as shown in FIG. 5. In FIG. 6, the first through hole 42 and the second through hole 52 can be formed by a suitable way, such as mechanical drilling or laser drilling, and the first and second through holes 42 and 52 are configured with the shape wider at the outside and narrower at the inside, i.e. W2>W1 and W3>W4. For example, the vertical sections of the first and second through holes 42 and 52 in this embodiment are shaped as trapezoids.

Further speaking, the first substrate 30 usually has a plurality of first electrically conductive pads 32, and the second substrate 60 usually has a plurality of second electrically conductive pads 62. Corresponding to this condition, in the step b), the first insulating dielectric layer 40 is provided with a plurality of first through holes 42 by drilling, which are directly connected with the first electrically conductive pads 32 respectively. In the step c), the second insulating dielectric layer 50 is provided with a plurality of second through holes 52 by drilling, which are directly connected with the second electrically conductive pads 62 respectively. The smallest distance between the upper ends 421 of the adjacent first through holes 42 is defined as a first upper interval d1. The smallest distance between the lower ends 422 of the adjacent first through holes 42 is defined as a first lower interval d2. The first lower interval d2 is smaller than the first upper interval d1. The smallest distance between the upper ends 522 of the adjacent second through holes 52 is defined as a second upper interval d3. The smallest distance between the lower ends 521 of the adjacent second through holes 52 is defined as a second lower interval d4. The second upper interval d3 is smaller than the second lower interval d4.

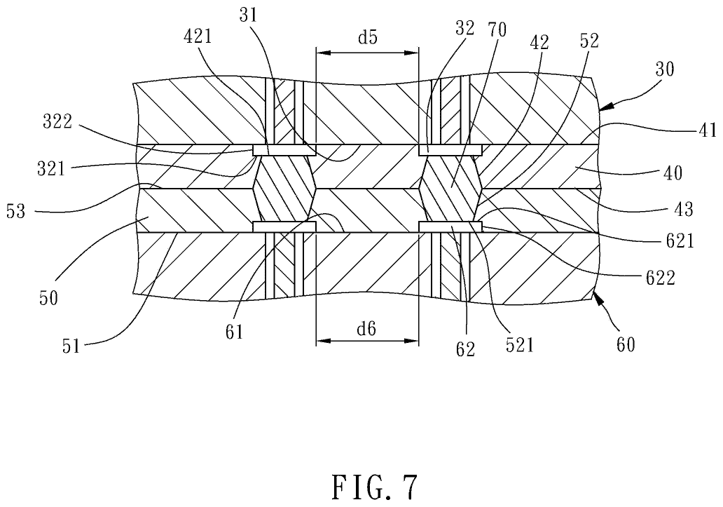

It is to be mentioned that the meaning of the aforementioned smallest distance can be specified by taking the first upper interval d1 as an example, wherein the first upper interval d1 is defined between the closest points of the upper ends 421 of the adjacent first through holes 42, so it is called the smallest distance.
d) As shown in FIG. 7, dispose an electrically conductive filler 70 in the first through hole 42 and the second through hole 52 and attach the lower surface 43 of the first insulating dielectric layer 40 and the upper surface 53 of the second insulating dielectric layer 50 to each other in a way that the upper end 522 of the second through hole 52 directly communicates with the lower end 422 of the first through hole 42, and the electrically conductive filler 70 is electrically connected with the first electrically conductive pad 32 and the second electrically conductive pad 62.

For example, this step d) can be performed in a way that the first through hole 42 and the second through hole 52 are firstly filled up with electrically conductive adhesive, and then the lower surface 43 of the first insulating dielectric layer 40 and the upper surface 53 of the second insulating dielectric layer 50 are attached to each other in a way that the upper end 522 of the second through hole 52 and the lower end 422 of the first through hole 42 are aligned with each other, so that the electrically conductive adhesive in the first through hole 42 and the electrically conductive adhesive in the second through hole 52 are connected with each other to become the electrically conductive filler 70. However, the electrically conductive filler 70 in the present invention is unlimited to be made of electrically conductive adhesive, as long as the electrically conductive filler 70 can be disposed in at least one of the first and second through holes 42 and 52 before the first and second insulating dielectric layers 40 and 50 are attached to each other, and the electrically conductive filler 70 can be located in both the first and second through holes 42 and 52 and connected with the first and second electrically conductive pads 32 and 62 after the first and second insulating dielectric layers 40 and 50 are attached to each other.

In the aforementioned condition that the first and second substrates 30 and 60 have a plurality of first and second electrically conductive pads 32 and 62 respectively and the first and second insulating dielectric layers 40 and 50 correspondingly have a plurality of first and second through holes 42 and 52 respectively, this step d) is disposing an electrically conductive filler 70 in every set of first and second through holes 42 and 52 communicating with each other, which means the circuit board 20 has a plurality of electrically conductive fillers 70.

By the aforementioned steps a) to d), the circuit board 20 as shown in FIG. 3 can be manufactured. As described above, the lower surface 43 of the first insulating dielectric layer 40 and the upper surface 53 of the second insulating dielectric layer 50 are not affected by the unevenness of the surfaces of the first and second substrates 30 and 60, so the lower surface 43 of the first insulating dielectric layer 40 and the upper surface 53 of the second insulating dielectric layer 50 are attached to each other in a quite flat manner, making the electrically conductive filler 70 electrically connected with the first electrically conductive pad 32 and the second electrically conductive pad 62 positively, thereby preventing the circuit board 20, after the manufacture thereof is accomplished, from the open circuit problem. Besides, compared with the widths of where the first and second through holes 42 and 52 are connected with the first and second electrically conductive pads 32 and 62, i.e. W1 and W4, the widths of the openings of the first and second through holes 42 and 52 located on the lower surface 43 of the first insulating dielectric layer 40 and the upper surface 53 of the second insulating dielectric layer 50, i.e. W2 and W3, are made larger. By this feature, i.e. W2>W1 and W3>W4, during attaching the lower surface 43 of the first insulating dielectric layer 40 and the upper surface 53 of the second insulating dielectric layer 50 to each other, it is relatively easier to align the first through hole 42 and the second through hole 52 with each other, causing the alignment process great accuracy, thereby improving the circuit integrity.

Although where the first and second insulating dielectric layers 40 and 50 are connected with each other being provided with the relatively wider openings of the first and second through holes 42 and 52, i.e. W2>W1 and W3>W4, correspondingly causes where the first and second insulating dielectric layers 40 and 50 are connected with each other to be provided with the relatively smaller intervals of the first and second through holes 42 and 52, i.e. d2<d1 and d3<d4, which means the first and second insulating dielectric layers 40 and 50 have reduced attached area, the first and second insulating dielectric layers 40 and 50 can be made of the same material and thereby can be still attached to each other firmly.

Relatively, the first and second insulating dielectric layers 40 and 50 are usually made of a material different from that of the first and second substrates 30 and 60, so the respective attachment of the first and second insulating dielectric layers 40 and 50 to the first and second substrates 30 and 60 needs relatively larger bonding force. In particular, the circuit board will be developed on the trend of the configuration with smaller interval between the electrically conductive pads, which will be more unfavorable to the bonding force of the attachment of the insulating dielectric layer and the substrate to each other. Therefore, the configuration improved in the bonding force between the insulating dielectric layer and the substrate is more important. Specifically speaking, referring to FIG. 7, in the condition that the interval d5 between the first electrically conductive pads 32 and the interval d6 between the second electrically conductive pads 62 are very small, such as those in the BGA region, the part of the area of the lower surface 31 of the first substrate 30 located between the adjacent first electrically conductive pads 32 for the first insulating dielectric layer 40 to be attached thereto, i.e. the attached area provided by the interval d5, is very small, and the part of the area of the upper surface 61 of the second substrate 60 located between the adjacent second electrically conductive pads 62 for the second insulating dielectric layer 50 to be attached thereto, i.e. the attached area provided by the interval d6, is very small. However, in the present invention, referring to FIG. 3, the first and second through holes 42 and 52 have relatively smaller width at the ends thereof connected with the first and second electrically conductive pads 32 and 62, i.e. W1<W2 and W4<W3. That correspondingly causes relatively larger intervals to the ends of the first and second through holes 42 and 52 connected with the first and second electrically conductive pads 32 and 62, i.e. d1>d2 and d4>d3, so that where the first and second insulating dielectric layers 40 and 50 are attached to the first and second substrates 30 and 60 respectively is larger in area than where the first and second insulating dielectric layers 40 and 50 are attached to each other. This feature can prevent the first and second insulating dielectric layers 40 and 50 from having too small area thereof to be attached to the first and second substrates 30 and 60, so as to ensure enough bonding force between the first and second insulating dielectric layers 40 and 50 and the first and second substrates 30 and 60, thereby avoiding the substrate coming off problem.

Further speaking, as shown in FIG. 7, in this embodiment, the first electrically conductive pad 32 of the first substrate 30 has a bottom surface 321 directly connected with the upper end 421 of the first through hole 42, and an outer peripheral surface 322 located on the outer periphery of the bottom surface 321. The first insulating dielectric layer 40 is attached to the outer peripheral surface 322 and the partial bottom surface 321 of the first electrically conductive pad 32. Likewise, the second electrically conductive pad 62 of the second substrate 60 has a top surface 621 directly connected with the lower end 521 of the second through hole 52, and an outer peripheral surface 622 located on the outer periphery of the top surface 621. The second insulating dielectric layer 50 is attached to the outer peripheral surface 622 and the partial top surface 621 of the second electrically conductive pad 62. In this way, the attached area between the first insulating dielectric layer 40 and the first substrate 30 includes the attached area provided by the interval d5 between the first electrically conductive pads 32, and the attached area between the first insulating dielectric layer 40 and the outer peripheral surfaces 322 and the partial bottom surfaces 321 of the first electrically conductive pads 32. The attached area between the second insulating dielectric layer 50 and the second substrate 60 includes the attached area provided by the interval d6 between the second electrically conductive pads 62, and the attached area between the second insulating dielectric layer 50 and the outer peripheral surfaces 622 and the partial top surfaces 621 of the second electrically conductive pads 62. That makes the attached area between the first and second insulating dielectric layers 40 and 50 and the first and second substrates 30 and 60 relatively larger. In particular, in the condition that the intervals d5 and d6 of the first and second electrically conductive pads are very small, such as those in the BGA region, this feature is effective in increasing the attached area between the first and second insulating dielectric layers 40 and 50 and the first and second substrates 30 and 60, so as to improve the bonding force between the first and second insulating dielectric layers 40 and 50 and the first and second substrates 30 and 60.

Besides, as shown in FIG. 3, in this embodiment, the first upper interval d1 between the first through holes 42 is larger than the first upper width W1, and the second lower interval d4 between the second through holes 52 is larger than the second lower width W4. As a result, where the first and second insulating dielectric layers 40 and 50 are attached to the first and second substrates 30 and 60 is larger in area than where the first and second through holes 42 and 52 are connected with the first and second substrates 30 and 60, which can further ensure enough bonding force between the first and second insulating dielectric layers 40 and 50 and the first and second substrates 30 and 60, thereby avoiding the substrate coming off problem.

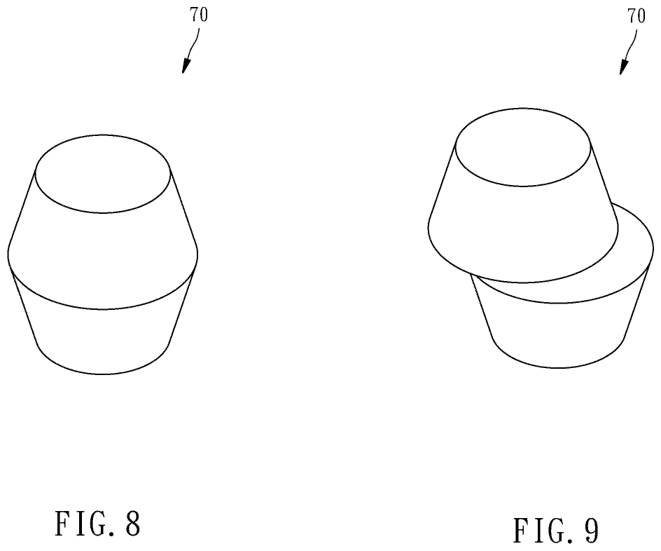

It is to be mentioned that although the technical features of the present invention can cause the alignment of the first through hole 42 and the second through hole 52 with each other relatively higher accuracy, ensuring the associated first and second through holes 42 and 52 to communicate with each other for the electrically conductive filler 70 to be disposed therein and electrically connected with the first and second electrically conductive pads 32 and 62, the associated first and second through holes 42 and 52 may be not completely aligned with each other accurately. For example, in the condition that the associated first and second through holes 42 and 52 are completely aligned with each other accurately, the electrically conductive filler 70 is shaped as shown in FIG. 8. However, in the condition that the associated first and second through holes 42 and 52 are not completely aligned with each other accurately, which means they have a slight offset but still communicate with each other, the electrically conductive filler 70 may be shaped as shown in FIG. 9.

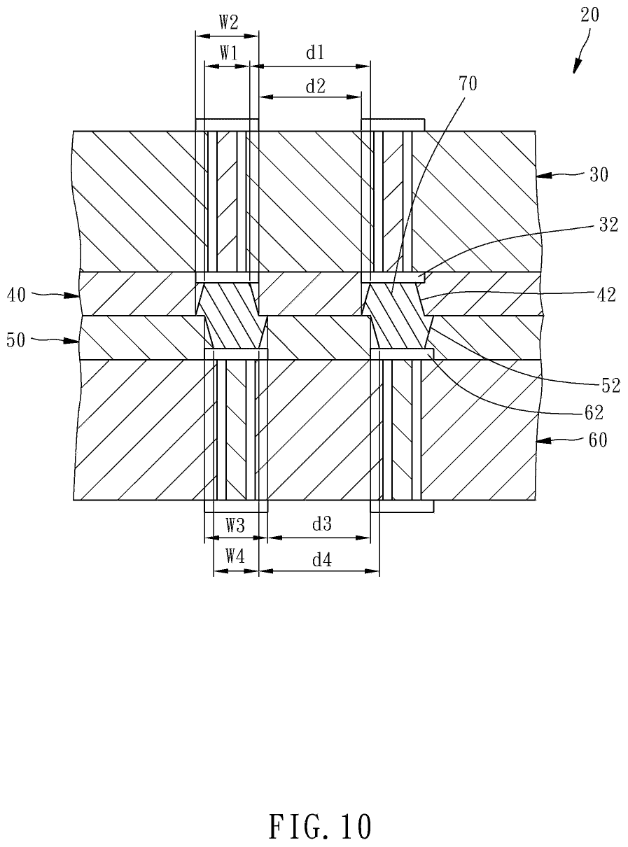

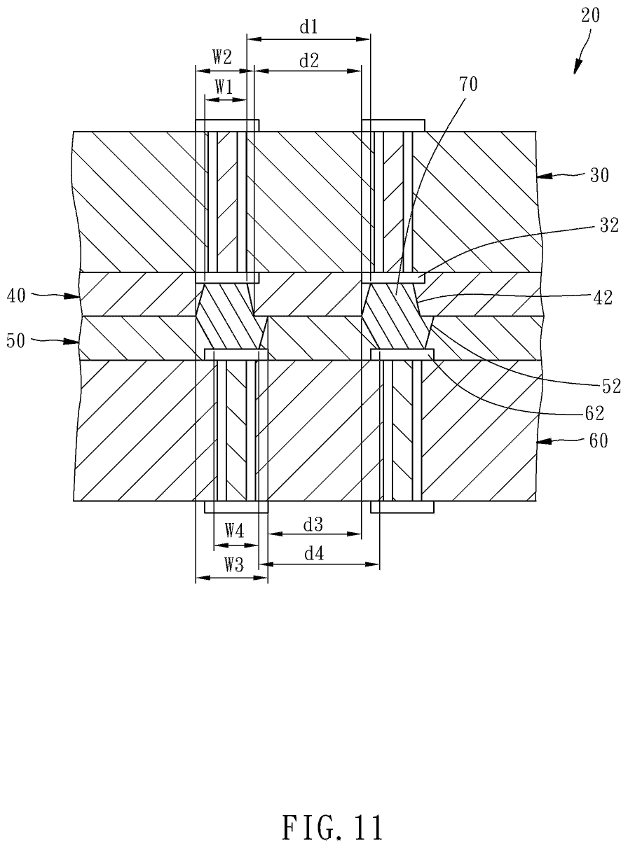

In the condition that the first and second through holes 42 and 52 are not completely aligned with each other accurately, if the circuit board 20 is sliced vertically for the observation of the vertical sectional configuration thereof, it may be sliced at different positions thereof and thereby the vertical sectional configuration as shown in FIG. 10 or FIG. 11 may be obtained. More specifically speaking, different sliced positions may cause different relation between the widths W1-W4 and the intervals d1-d4 of the first and second through holes 42 and 52. For example, although the first and second through holes 42 and 52 shown in FIG. 10 have an offset, the widths W1-W4 and the intervals d1-d4 thereof are all approximately the same with those shown in FIG. 3. However, the relation between the widths W1-W4 and the intervals d1-d4 of the first and second through holes 42 and 52 shown in FIG. 11 is obviously different from that shown in FIG. 3 and FIG. 10. For example, compared with those shown in FIG. 10, in FIG. 11 the first lower width W2 is smaller but the second upper width W3 is larger. It can be seen that although in FIG. 3 the first upper width W1 equals to the second lower width W4, the first lower width W2 equals to the second upper width W3, the first upper interval d1 equals to the second lower interval d4 and the first lower interval d2 equals to the second upper interval d3, the present invention is unlimited thereto. As long as W2>W1 and W3>W4, or d2<d1 and d3<d4, the size features of the first and second through holes 42 and 52 defined by the present invention are met.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A circuit board for a semiconductor testing, the circuit board comprising:
a first substrate having a lower surface, and at least one first electrically conductive pad located on the lower surface of the first substrate;
a second substrate having an upper surface, and at least one second electrically conductive pad located on the upper surface of the second substrate;
a first insulating dielectric layer having an upper surface, a lower surface and at least one first through hole, the upper surface of the first insulating dielectric layer being attached to the lower surface of the first substrate, the first through hole having an upper end and a lower end, the upper end of the first through hole being directly connected with the first electrically conductive pad, the upper end and the lower end of the first through hole having a first upper width and a first lower width respectively, the first lower width being larger than the first upper width;
a second insulating dielectric layer having an upper surface, a lower surface and at least one second through hole, the upper surface and the lower surface of the second insulating dielectric layer being attached to the lower surface of the first insulating dielectric layer and the upper surface of the second substrate respectively, the second through hole having an upper end and a lower end, the lower end of the second through hole being directly connected with the second electrically conductive pad, the upper end of the second through hole directly communicating with the lower end of the first through hole, the upper end and the lower end of the second through hole having a second upper width and a second lower width respectively, the second upper width being larger than the second lower width; and
at least one electrically conductive filler disposed in the first through hole and the second through hole and electrically connected with the first electrically conductive pad and the second electrically conductive pad.

2. The circuit board as claimed in claim 1, wherein the first electrically conductive pad of the first substrate has a bottom surface directly connected with the upper end of the first through hole, and an outer peripheral surface located on an outer periphery of the bottom surface; the first insulating dielectric layer is attached to the outer peripheral surface and a part of the bottom surface of the first electrically conductive pad; the second electrically conductive pad of the second substrate has a top surface directly connected with the lower end of the second through hole, and an outer peripheral surface located on an outer periphery of the top surface; the second insulating dielectric layer is attached to the outer peripheral surface and a part of the top surface of the second electrically conductive pad.

3. The circuit board as claimed in claim 1, wherein the first substrate comprises a plurality of said first electrically conductive pads; the first insulating dielectric layer has a plurality of said first through holes; the upper ends of the first through holes are directly connected with the first electrically conductive pads respectively; a smallest distance between the upper ends of two adjacent said first through holes is defined as a first upper interval; the first upper interval is larger than the first upper width; the second substrate has a plurality of said second electrically conductive pads; the second insulating dielectric layer has a plurality of said second through holes; the upper ends of the second through holes directly communicate with the lower ends of the first through holes respectively; the lower ends of the second through holes are directly connected with the second electrically conductive pads respectively; a smallest distance between the lower ends of two adjacent said second through holes is defined as a second lower interval; the second lower interval is larger than the second lower width.

4. The circuit board as claimed in claim 3, wherein a smallest distance between the lower ends of two adjacent said first through holes is defined as a first lower interval; the first lower interval is smaller than the first upper interval; a smallest distance between the upper ends of two adjacent said second through holes is defined as a second upper interval; the second upper interval is smaller than the second lower interval.

5. A circuit board for a semiconductor testing, the circuit board comprising:
a first substrate having a lower surface, and a plurality of first electrically conductive pads located on the lower surface of the first substrate;
a second substrate having an upper surface, and a plurality of second electrically conductive pads located on the upper surface of the second substrate;
a first insulating dielectric layer having an upper surface, a lower surface and a plurality of first through holes, the upper surface of the first insulating dielectric layer being attached to the lower surface of the first substrate, each of the first through holes having an upper end and a lower end, the upper ends of the first through holes being directly connected with the first electrically conductive pads respectively, a smallest distance between the upper ends of two adjacent said first through holes being defined as a first upper interval, a smallest distance between the lower ends of two adjacent said first through holes being defined as a first lower interval, the first lower interval being smaller than the first upper interval;
a second insulating dielectric layer having an upper surface, a lower surface and a plurality of second through holes, the upper surface and the lower surface of the second insulating dielectric layer being attached to the lower surface of the first insulating dielectric layer and the upper surface of the second substrate respectively, each of the second through holes having an upper end and a lower end, the lower ends of the second through holes being directly connected with the second electrically conductive pads respectively, the upper ends of the second through holes directly communicating with the lower ends of the first through holes respectively, a smallest distance between the lower ends of two adjacent said second through holes being defined as a second lower interval, a smallest distance between the upper ends of two adjacent said second through holes being defined as a second upper interval, the second upper interval being smaller than the second lower interval; and
a plurality of electrically conductive fillers, each of the electrically conductive fillers being disposed in the first through hole and the second through hole, which are communicated with each other, and electrically connected with one of the first electrically conductive pads and one of the second electrically conductive pads.

6. The circuit board as claimed in claim 5, wherein the upper end and the lower end of each of the first through holes have a first upper width and a first lower width respectively; the first upper interval is larger than the first upper width; the upper end and the lower end of each of the second through holes have a second upper width and a second lower width respectively; the second lower interval is larger than the second lower width.

7. The circuit board as claimed in claim 5, wherein the upper end and the lower end of each of the first through holes have a first upper width and a first lower width respectively; the first lower width is larger than the first upper width; the upper end and the lower end of each of the second through holes have a second upper width and a second lower width respectively; the second upper width is larger than the second lower width.

8. The circuit board as claimed in claim 5, wherein each of the first electrically conductive pads of the first substrate has a bottom surface directly connected with the upper end of one of the first through holes, and an outer peripheral surface located on an outer periphery of the bottom surface; the first insulating dielectric layer is attached to the outer peripheral surface and a part of the bottom surface of each of the first electrically conductive pads; each of the second electrically conductive pads of the second substrate has a top surface directly connected with the lower end of one of the second through holes, and an outer peripheral surface located on an outer periphery of the top surface; the second insulating dielectric layer is attached to the outer peripheral surface and a part of the top surface of each of the second electrically conductive pads.

9. A method of manufacturing the circuit board of claim 1, the method comprising the steps of:
providing a first substrate and a second substrate, the first substrate having a lower surface and at least one first electrically conductive pad located on the lower surface of the first substrate, the second substrate having an upper surface and at least one second electrically conductive pad located on the upper surface of the second substrate;
providing a first insulting dielectric layer having an upper surface attached to the lower surface of the first substrate; wherein the first insulting dielectric layer is configured as having at least one first through hole made by drilling in a way that an upper end of the first through hole is directly connected with the first electrically conductive pad, a lower end of the first through hole is located on a lower surface of the first insulating dielectric layer, the upper end and the lower end of the first through hole have a first upper width and a first lower width respectively, and the first lower width is larger than the first upper width;
providing a second insulating dielectric layer having a lower surface attached to the upper surface of the second substrate; wherein the second insulating dielectric layer is configured as having at least one second through hole made by drilling in a way that a lower end of the second through hole is directly connected with the second electrically conductive pad, an upper end of the second through hole is located on an upper surface of the second insulating dielectric layer, the upper end and the lower end of the second through hole have a second upper width and a second lower width respectively, and the second upper width is larger than the second lower width; and
providing an electrically conductive filler disposed in the first through hole and the second through hole in a way that the lower surface of the first insulating dielectric layer is attached to the upper surface of the second insulating dielectric layer, the upper end of the second through hole directly communicates with the lower end of the first through hole, and the electrically conductive filler is electrically connected with the first electrically conductive pad and the second electrically conductive pad.

10. A method of manufacturing the circuit board of claim 5, the method comprising the steps of:
providing a first substrate and a second substrate, the first substrate having a lower surface and a plurality of first electrically conductive pads located on the lower surface of the first substrate, the second substrate having an upper surface and a plurality of second electrically conductive pads located on the upper surface of the second substrate;
providing a first insulating dielectric layer having an upper surface attached to the lower surface of the first substrate; wherein the first insulating dielectric layer is configured as having a plurality of first through holes made by drilling and each having an upper end and a lower end in a way that the upper ends of the first through holes are directly connected with the first electrically conductive pads respectively, the lower ends of the first through holes are located on a lower surface of the first insulating dielectric layer, a smallest distance between the upper ends of two adjacent said first through holes is defined as a first upper interval, a smallest distance between the lower ends of two adjacent said first through holes is defined as a first lower interval, and the first lower interval is smaller than the first upper interval;
providing a second insulating dielectric layer having a lower surface attached to the upper surface of the second substrate; wherein the second insulating dielectric layer is configured as having a plurality of second through holes made by drilling and each having an upper end and a lower end in a way that the lower ends of the second through holes are directly connected with the second electrically conductive pads respectively, the upper ends of the second through holes are located on an upper surface of the second insulating dielectric layer, a smallest distance between the lower ends of two adjacent said second through holes is defined as a second lower interval, a smallest distance between the upper ends of two adjacent said second through holes is defined as a second upper interval, and the second upper interval is smaller than the second lower interval; and
providing a plurality of electrically conductive fillers disposed in the first through holes and the second through holes in a way that the lower surface of the first insulating dielectric layer is attached to the upper surface of the second insulating dielectric layer, the upper ends of the second through holes directly communicate with the lower ends of the first through holes respectively, and each of the electrically conductive fillers is disposed in the first through hole and the second through hole, which are communicated with each other, and electrically connected with one of the first electrically conductive pads and one of the second electrically conductive pads.
